(19) United States
(12) Patent Application Publication
(10) Pub. No.: US 2023/0321905 A1
(43) Pub. Date: Oct. 12, 2023

(54) 3D PRINTER USING SCREW EXTRUDER

(71) Applicant: MEDIFAB CO., LTD., Seoul (KR)

(72) Inventor: Mi Sun CHA, Seoul (KR)

(21) Appl. No.: 18/023,629

(22) PCT Filed: Aug. 11, 2021
(86) PCT No.: PCT/KR2021/010636

§ 371 Date: Feb. 27, 2023

(30) Foreign Application Priority Data
Aug. 28, 2020 (KR) 10-2020-0109489

(51) Int. Cl. B29C 64/209; B29C 64/118; B33Y 30/00; B33Y 50/02; B29C 64/393

(52) U.S. Cl. CPC B29C 64/209; B29C 64/118; B33Y 30/00; B33Y 50/02; B29C 64/393

(57) ABSTRACT

The disclosure relates to a 3D printer using a screw extruder, including a housing including a driving motor, a dispenser in which raw materials are stored and including a nozzle through which raw materials are sprayed, a screw extruder including a screw forming unit arranged inside the dispenser, having a rod shape, and including a spiral screw formed on an outer circumferential surface, and an extension portion extending from the screw forming unit to outside of the dispenser, and an accommodating portion provided in the housing and to which the dispenser is coupled, wherein the dispenser is detachably coupled to the accommodating portion of the housing.

### TECHNICAL FIELD

The disclosure relates to a 3D printer using a screw extruder, and more particularly, to a 3D printer using a screw extruder, in which cleaning and sterilizing of the 3D printer may be easily performed as a dispenser including a screw forming unit in which a spiral screw is formed is replaceably coupled to a housing of the 3D printer.

### BACKGROUND ART

A three-dimensional (3D) printer refers to a device that outputs a three-dimensional shape of a real object by stacking layers with a fine thickness while sequentially spraying certain materials through a nozzle. Raw materials used in 3D printers may be metals, synthetic resins, or the like. Recently, bio-3D printers using biomaterials as materials have been developed.

A 3D printer outputs a three-dimensional shape of a real object while extruding a raw material through a screw extruder structure in which a spiral screw is formed, and the 3D printer produces various shapes by using various raw materials. However, 3D printers in the related art have the following problems.

A 3D printer in the related art outputs a three-dimensional shape through a screw extruder structure in which a spiral screw is formed, but it is difficult to clean or sterilize the screw extruder structure in the related art as the screw extruder structure is integrated with a housing of the 3D printer.

In particular, in the case of bio-3D printing using biomaterials as raw materials, a screw extruder structure of the 3D printer must be cleaned and sterilized to replace the raw materials including biomaterials. When cleaning and sterilizing of previously used raw materials are not carried out, old raw materials and new raw materials are mixed, and the 3D printer cannot output a three-dimensional shape of a target object.

However, in the case of a bio-3D printer in the related art, cleaning or sterilizing of the 3D printer is difficult because a housing thereof is integrally formed with a screw extruder structure.

### DESCRIPTION OF EMBODIMENTS

### Technical Problem

The disclosure is to solve the above problems, and more particularly, relates to a 3D printer using a screw extruder, in which cleaning and sterilizing of the 3D printer may be easily performed as a dispenser including a screw forming unit in which a spiral screw is formed is coupled to a housing of the 3D printer in a replaceable manner.

### Solution to Problem

A 3D printer using a screw extruder includes a housing including a driving motor, a dispenser in which raw materials are stored and including a nozzle through which raw materials are sprayed, a screw extruder including a screw forming unit arranged inside the dispenser, having a rod shape, and including a spiral screw formed on an outer circumferential surface, and an extension portion extending from the screw forming unit to outside of the dispenser, and an accommodating portion provided in the housing and to which the dispenser is coupled, wherein the dispenser is detachably coupled to the accommodating portion of the housing.

In the 3D printer using the screw extruder, the accommodating portion may have one surface open toward outside, and the 3D printer may further include a cover portion coupled to the one surface of the accommodating portion.

In the 3D printer using the screw extruder, the dispenser may include a material replenishing port configured to inject raw materials into the dispenser.

The 3D printer using the screw extruder may further include a screw connector connecting the driving motor and the extension portion of the screw extruder to each other.

In the 3D printer using the screw extruder, a key groove into which the extension portion is able to be inserted may be formed at a lower portion of the screw connector, and an upper portion of the extension portion may be provided with a coupling key having a shape corresponding to a shape of the key groove to be able to be inserted into the key groove.

In the 3D printer using the screw extruder, a first spring capable of applying an elastic restoring force to the extension portion may be provided at an upper portion of the key groove.

In the 3D printer using the screw extruder, a first spring capable of applying an elastic restoring force to the extension portion may be provided at an upper portion of the key groove, and a spring plate in contact with the coupling key of the extension portion may be provided between the first spring and the key groove.

In the 3D printer using the screw extruder, the screw forming unit may include a first screw forming unit arranged at a lower portion of the dispenser and a second screw forming unit arranged at an upper portion of the dispenser, and an inclination formed by a second screw of the second screw forming unit may be higher than an inclination formed by a first screw of the first screw forming unit.

In the 3D printer using the screw extruder, a sealing unit capable of sealing an upper portion of the screw forming unit may be provided at a lower portion of the extension portion.

In the 3D printer using the screw extruder, the sealing unit may be slidably coupled between the screw forming unit and the coupling key of the extension portion, and a second spring may be inserted between the coupling key of the extension portion and the sealing unit.

The 3D printer using the screw extruder may further include a Peltier element having one side and another side being cooled or heated according to a direction of a supplied current and coupled to the dispenser, and a heater coupled to the dispenser and configured to transfer heat to the dispenser.

The 3D printer using the screw extruder may further include a sensor unit capable of measuring a temperature of the raw materials stored in the dispenser, and a controller configured to control the Peltier element and the heater according to a temperature sensed by the sensor unit, wherein the controller may operate the heater when the temperature sensed by the sensor unit is lower than a designated temperature, and may operate the Peltier element when the temperature sensed by the sensor unit is higher than the designated temperature.

In the 3D printer using the screw extruder, the dispenser may include a heating block provided at a lower portion of the dispenser and a heat blocking unit provided at an upper portion of the dispenser, and a material of the heating block may have a higher thermal conductivity than a material of the heat blocking unit.

In the 3D printer using the screw extruder, the housing may include a magnet configured to fix the housing to a support.

In the 3D printer using the screw extruder, the housing may include a through hole into which a support rod is inserted, and the support rod may be coupled to a support configured to fix the housing.

The disclosure was created through a national project corresponding to the following information: Project Unique Number: 1425136551, Department Name: Ministry of Small and Medium Business, Research Management Specialist Organization: Small and Medium Business Technology Information Agency, Research Project Name: Development of startup growth technology (R&D), Title of Research Project: Development of hybrid implant technology for facial tissue restoration using 3D printing-based autologous tissue-inducing functional biomaterials, Organizer: Medifab Co., Ltd., and Research Period: 2020 Dec. 2˜2021 Dec. 1.

The disclosure was created through a national project corresponding to the following information: Project Unique Number: 1415168659, Department Name: Ministry of Trade, Industry and Energy, Research Management Specialist Organization: Korea Evaluation Institute of Industrial Technology, Research Project Name: Development of startup growth technology (R&D), Title of Research Project: Development of commercialization technology for regenerative medicine through the development of tissue-derived extracellular matrix-based bioink, Executing Organization: Medifab Co., Ltd., and Research Period: 2021 Jan. 1˜2021 Dec. 31.

### Advantageous Effects of Disclosure

The disclosure relates to a 3D printer using a screw extruder, in which cleaning and sterilizing of the 3D printer may be easily performed as a dispenser including a screw forming unit in which a spiral screw is formed is coupled to a housing of the 3D printer in a replaceable manner.

In addition, in the disclosure, a key groove is provided in a screw connector, and a coupling key is provided on an extension portion of a screw forming unit, and thus a driving motor may be easily coupled to the screw forming unit.

### BRIEF DESCRIPTION OF DRAWINGS

FIG. 1 is a diagram showing a 3D printer using a screw extruder, according to an embodiment;

FIG. 2 is a diagram showing a dispenser and a screw extruder of a 3D printer using a screw extruder, according to an embodiment;

FIGS. 3A and 3B are diagrams showing a dispenser and a cover portion, which are detachably coupled to an accommodating portion, according to an embodiment;

FIG. 4A is an enlarged view of a region ‘A’ of FIG. 3A, and FIG. 4B is a diagram showing a screw extruder and a screw connector, according to an embodiment;

FIG. 5 is a diagram showing a screw extruder according to an embodiment;

FIG. 6 is a diagram showing coupling of a second spring to a screw extruder according to an embodiment;

FIG. 7 is a diagram showing a heating block and a heat blocking unit, provided in a dispenser according to an embodiment;

FIG. 8 is a diagram showing a Peltier element and a heatsink, provided in a dispenser according to an embodiment;

FIG. 9 is a diagram showing a housing capable of being coupled to a fixed support or a work support, according to an embodiment; and

FIG. 10 is a diagram showing a magnet and a through hole, provided in a housing according to an embodiment.

### MODE OF DISCLOSURE

The disclosure will now be described more fully with reference to the accompanying drawings, in which embodiments of the disclosure are shown. The disclosure may, however, be embodied in many different forms and should not be construed as being limited to the embodiments set forth herein. Rather, these embodiments are provided so that this disclosure will be thorough and complete, and will fully convey the concept of the disclosure to those skilled in the art.

In various embodiments, terms “including” or “may include” or the like indicate the existence of a corresponding function, operation, or component, and one or more additional functions, operations, or components are not limited. In addition, it is to be understood that the terms such as “including,” “having,” and “comprising” are intended to indicate the existence of the features, numbers, steps, actions, components, parts, or combinations thereof disclosed in the disclosure, and are not intended to preclude the possibility that one or more other features, numbers, steps, actions, components, parts, or combinations thereof may exist or may be added.

It will be understood that when a component is referred to as being “connected and coupled to” another component, the component can be directly connected or coupled the other component or intervening components may be present therebetween. On the contrary, it will be understood that when a component is referred to as being “directly connected and coupled to” another component, intervening components may not be present therebetween.

In the disclosure, while h terms as “first,” “second,” etc., may be used to describe various components, such components must not be limited to the above terms. The above terms are used only to distinguish one component from another.

The disclosure relates to a three-dimensional (3D) printer using a screw extruder, and relates to a 3D printer using a screw extruder, in which cleaning and sterilizing of the 3D printer may be easily performed as a dispenser including a screw forming unit in which a spiral screw is formed is coupled to a housing of the 3D printer in a replaceable manner. The disclosure will now be described more fully with reference to the accompanying drawings, in which embodiments of the disclosure are shown.

A 3D printer using a screw extruder, according to an embodiment, includes a housing 110, a dispenser 120, a screw extruder 130, and an accommodating portion 160.

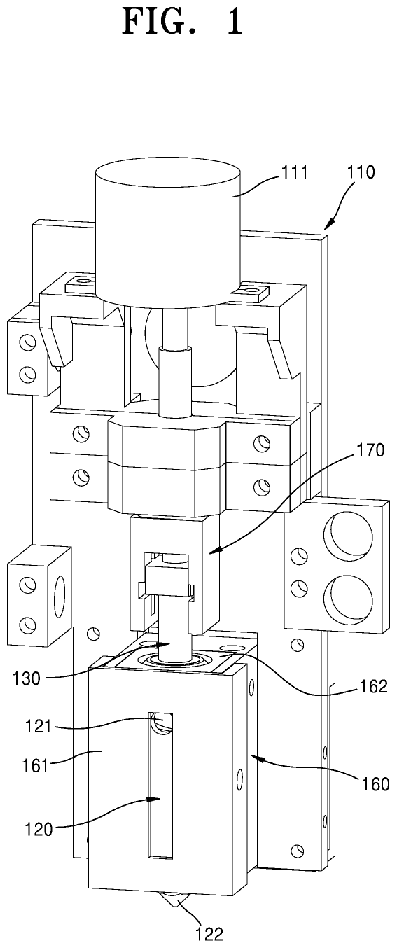

Referring to FIG. 1, the housing 110 includes a driving motor 111, and may be a frame of the 3D printer. In the housing 110, the dispenser 120, the screw extruder 130, and the accommodating portion 160, which are described below, may be provided.

The driving motor 111 may rotate the screw extruder 130 while being connected to the screw extruder 130. When the screw extruder 130 is rotated through the rotation of the driving motor 111, printing is performed while a screw forming unit 140 having a spiral shape, which is provided in the screw extruder 130, extrudes a raw material.

The dispenser 120 includes a nozzle 122 through which a raw material is sprayed when the raw material is stored. The dispenser 120 includes a space in which a raw material may be stored, and printed is performed while the raw material stored in the dispenser 120 is sprayed through the nozzle 122.

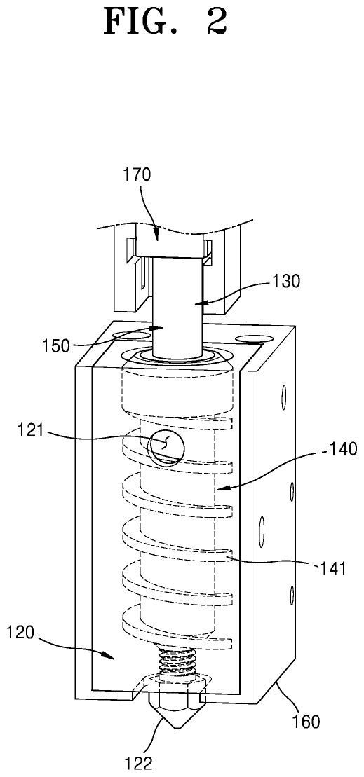

Referring to FIG. 2, a material replenishing port 121 configured to inject a raw material into the dispenser 120 may be provided in the dispenser 120. The material replenishing port 121 communicates with an inner space of the dispenser 120, and a user may inject a raw material into the dispenser 120 through the material replenishing port 121. The material replenishing port 121 may be provided with an opening and closing portion capable of opening and closing the material replenishing port 121.

The screw extruder 130 includes the screw forming unit 140 arranged inside the dispenser 120, having a rod shape, and on which a screw 141 having a spiral shape is formed on an outer circumferential surface thereof, and an extension portion 150 extending from the screw forming unit 140 to the outside of the dispenser 120.

The screw extruder 130 may extrude a raw material inside the dispenser 120 through the rotation of the screw 141, and the screw extruder 130 may be connected to the driving motor 111 through a screw connector 170.

When the driving motor 111 rotates, the screw connector 170 and the screw extruder 130 are rotated, and when the screw extruder 130 rotates, the screw 141 of the screw extruder 130 extrudes a raw material inside the dispenser 120 and sprays the raw material through the nozzle 122.

The screw forming unit 140 is a portion where the screw 141 having a spiral shape is formed in the screw extruder 130, and the screw forming unit 140 is provided inside the dispenser 120 while having a rod shape. The screw forming unit 140 may be arranged in the inner space of the dispenser 120 where a raw material is stored, and the raw material stored inside the dispenser 120 may be extruded and sprayed through the rotation of the screw 141.

The extension portion 150 is a portion extending from the screw forming unit 140 arranged inside the dispenser 120 to the outside of the dispenser 120, and the extension portion 150 may be connected to the screw connector 170. The extension portion 150 may have a rod shape, and the screw forming unit 140 may be connected to the screw connector 170 through the extension portion 150.

The accommodating portion 160 is provided in the housing 110 and coupled to the dispenser 120. The accommodating portion 160 is a point to which the dispenser 120 is coupled, and the accommodating portion 160 may have a groove corresponding to the shape of the dispenser 120 so that the dispenser 120 may be inserted therein.

The dispenser 120 may be detachably coupled to the accommodating portion 160 of the housing 110. Cleaning and sterilizing of a 3D printer in the related art is difficult because a screw extruder structure in which a spiral screw is formed is integrated with a housing of the 3D printer.

To solve the above problem, in the 3D printer using a screw extruder according to an embodiment, the dispenser 120 is detachably coupled to the housing 110, and to this end, the housing 110 is provided with the accommodating portion 160.

The dispenser 120 may be formed in various shapes as long as being able to be detachably coupled to the housing 110, and various structures may be used. According to an embodiment, the accommodating portion 160 may have one surface that is open toward the outside to detachably couple the dispenser 120, and a cover portion 161 may be coupled to the one surface of the accommodating portion 160.

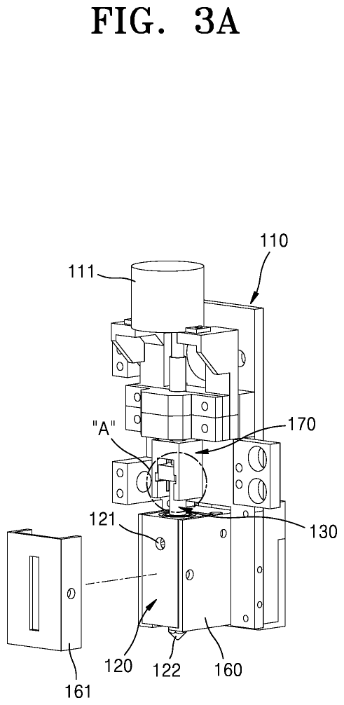

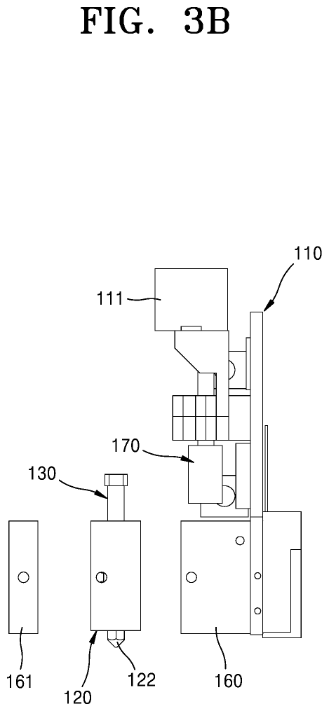

Referring to FIGS. 3A and 3B, the dispenser 120 may be coupled to the housing 110 by arranging the dispenser 120 in the accommodating portion 160 and covering one surface of the accommodating portion 160 with the cover portion 161.

The cover portion 161 is removed to detach the dispenser 120 from the housing 110, and the dispenser 120 is separated from the housing 110, so that the dispenser 120 may be detached from the housing 110. As the dispenser 120 is detached from the housing 110, the dispenser 120 may be cleaned and sterilized in a separate space.

A screw cover portion 162 capable of covering an upper portion of the dispenser 120 may also be provided on an upper portion of the accommodating portion 160. The screw cover portion 162 may be detachably coupled to the accommodating portion 160, and as the screw cover portion 162 is removed when the dispenser 120 is separated, the screw extruder 130 coupled to the dispenser 120 may be easily separated therefrom.

The dispenser 120 may be detached from the housing 110 through the accommodating portion 160 and the cover portion 161, but when the screw extruder 130 coupled to the dispenser 120 is integrally formed with the driving motor 111, it is difficult to separate the dispenser 120.

To this end, the 3D printer using the screw extruder according to an embodiment may further include the screw connector 170 connecting the driving motor 111 and the extension portion 150 of the screw extruder 130 to each other.

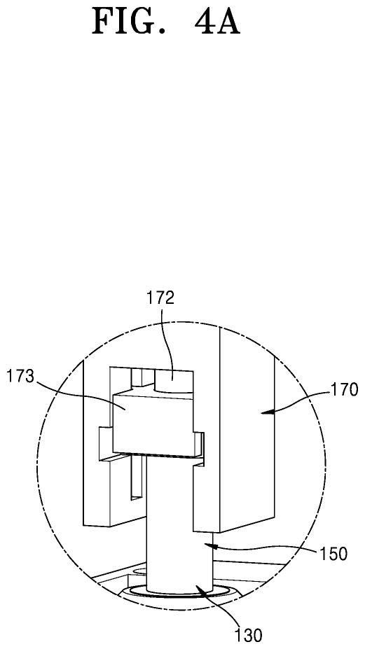

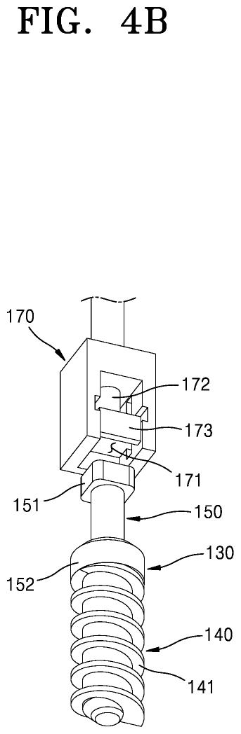

Referring to FIG. 4A, the screw connector 170 connects the extension portion 150 of the screw extruder 130 and the driving motor 111 to each other, and the extension portion 150 of the screw extruder 130 may be detachably coupled to the screw connector 170.

The screw connector 170 connects the extension portion 150 and the driving motor 111 to each other while being arranged between the extension portion 150 and the driving motor 111, and may be formed in various shapes as long as being able to connect the extension portion 150 and the driving motor 111 to each other.

According to an embodiment, because the screw connector 170 needs to transmit rotational power of the driving motor 111 to the extension portion 150 while connecting the extension portion 150 and the driving motor 111 to each other, the screw connector 170 preferably has a rod shape.

The screw connector 170 may be coupled to the driving motor 111 to rotate together with the driving motor 111, and when the screw connector 170 rotates due to the driving motor 111, the extension portion 150 coupled to the screw connector 170 may also rotate together.

The extension portion 150 of the screw extruder 130 may be formed in various shapes and have various structures to be detachably coupled to the screw connector 170.

According to an embodiment, a key groove 171 into which the extension portion 150 may be inserted may be formed at a lower portion of the screw connector 170 to detachably couple the extension portion 150 of the screw extruder 130 to the screw connector 170, and a coupling key 151 having a shape corresponding to the shape of the key groove 171 may be provided at an upper portion of the extension portion 150 to be inserted into the key groove 171.

Referring to FIG. 4B, the key groove 171 is a groove formed at the lower portion of the screw connector 170, and may be formed in a particular shape. The coupling key 151 may be formed in a shape corresponding to the shape of the key groove 171 to be inserted into the key groove 171.

When the coupling key 151 is inserted into the key groove 171, the extension portion 150 of the screw extruder 130 and the screw connector 170 may be connected to each other, and when the coupling key 151 is separated from the key groove 171, the extension portion 150 of the screw extruder 130 and the screw connector 170 may be separated from each other.

When the dispenser 120 is detached from the housing 110 to clean and sterilize the dispenser 120, the coupling key 151 of the extension portion 150 may be separated from the key groove 171 of the screw connector 170.

According to an embodiment, a sealing unit 152 capable of sealing an upper portion of the screw forming unit 140 may also be provided at a lower portion of the extension portion 150. The extension portion 150 is provided at an upper portion of the screw forming unit 140, and the sealing unit 152 may be provided at a point where the extension portion 150 and the screw forming unit 140 are connected to each other.

A hole into which the screw forming unit 140 may be inserted must be provided at an upper portion of the dispenser 120 such that the screw extruder 130 extends to the outside of the dispenser 120 while being arranged inside the dispenser 120.

The sealing unit 152 may seal the hole, and may prevent a raw material stored in the dispenser 120 from being discharged through the hole.

The screw extruder 130 discharges the raw material through the nozzle 122 while extruding the raw material through rotation, and the raw material must be discharged through the nozzle 122 while pressurizing the raw material through the screw extruder 130.

However, when the raw material includes a liquid material, there is a risk that the raw material is discharged through the hole of the dispenser 120 while a backflow phenomenon occurs. In particular, when the extension portion 150 is detachably coupled to the screw connector 170, it is difficult to prevent a phenomenon in which the raw material flows back into the hole of the dispenser 120 due to insufficient force for pressurizing the screw extruder 130.

To prevent the above case, pneumatic pressure may be applied to the screw extruder 130, but a manufacturing cost of a 3D printer increases when a device for applying pneumatic pressure is added. The 3D printer using the screw extruder according to an embodiment may arrange a first spring 172 at an upper portion of the key groove 171 to solve the above case.

Referring to FIG. 4B, the first spring 172 applies an elastic restoring force to the extension portion 150 at the upper portion of the key groove 171, and may be compressed through the extension portion 150 when the extension portion 150 is inserted into the key groove 171.

As the extension portion 150 is pressurized through the first spring 172, pressure may be applied to the screw extruder 130, and accordingly, a backflow phenomenon of a raw material in the dispenser 120 may be prevented from occurring.

A spring plate 173 in contact with the coupling key 151 of the extension portion 150 may also be provided between the first spring 172 and the key groove 171. The spring plate 173 has one side in contact with the first spring 172 and another side in contact with the coupling key 151, and the elastic restoring force of the first spring 172 may also be applied to the extension portion 150 through the spring plate 173.

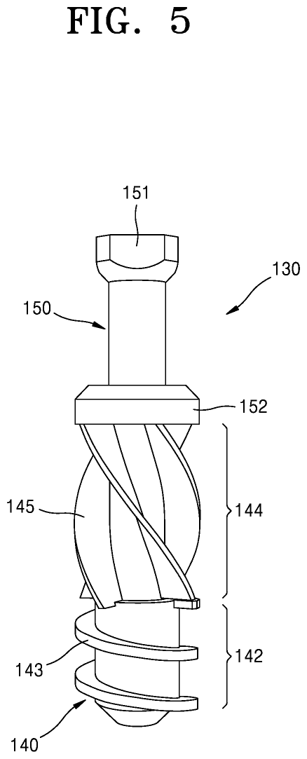

Referring to FIG. 5, the screw forming unit 140 may include a first screw forming unit 142 arranged at the lower portion of the dispenser 120 and a second screw forming unit 144 arranged at the upper portion of the dispenser 120.

A second screw 145 may be provided in the second screw forming unit 144, and a first screw 143 may be provided in the first screw forming unit 142. An inclination formed by the second screw 145 provided in the second screw forming unit 144 may be higher than an inclination formed by the first screw 143 provided in the first screw forming unit 142.

Here, a screw having a high inclination indicates that the screw extends to a higher height during one revolution. When the inclination of a screw is high, a moving distance of a raw material may be increased while the screw rotates one turn, and when the inclination of the screw is low, the moving distance of the raw material decreases, but pressure applied to the raw material may be increased.

When the inclination of the second screw 145 provided at the upper portion of the screw forming unit 140 is formed higher than the inclination of the first screw 143 provided at the lower portion of the screw forming unit 140, a raw material may be moved fast at the upper portion of the screw forming unit 140.

Also, at the lower portion of the screw forming unit 140 provided with the nozzle 122, the raw material may be efficiently discharged as the raw material is discharged at high pressure through the first screw 143 having a low inclination. Accordingly, the printing speed of a 3D printer may be improved.

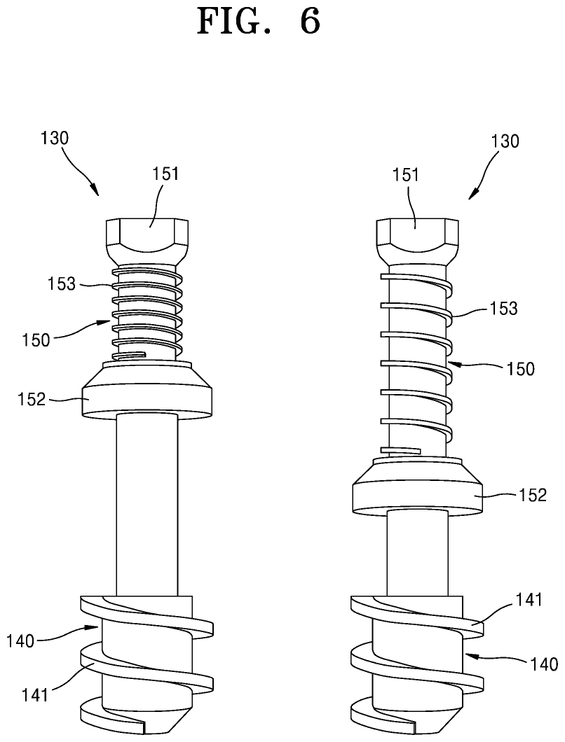

Referring to FIG. 6, the sealing unit 152 may be slidably coupled between the screw forming unit 140 and the coupling key 151 of the extension portion 150, and a second spring 153 may be inserted between the coupling key 151 of the extension portion 150 and the sealing unit 152.

When the second spring 153 is provided between the coupling key 151 and the sealing unit 152, the sealing unit 152 may be pressurized through the second spring 153. When the sealing unit 152 is pressurized, a raw material inside the dispenser 120 may be discharged while being pressurized by the sealing unit 152. Accordingly, an output efficiency of the 3D printer may be increased, and a backflow phenomenon of a raw material in the dispenser 120 may be prevented from occurring.

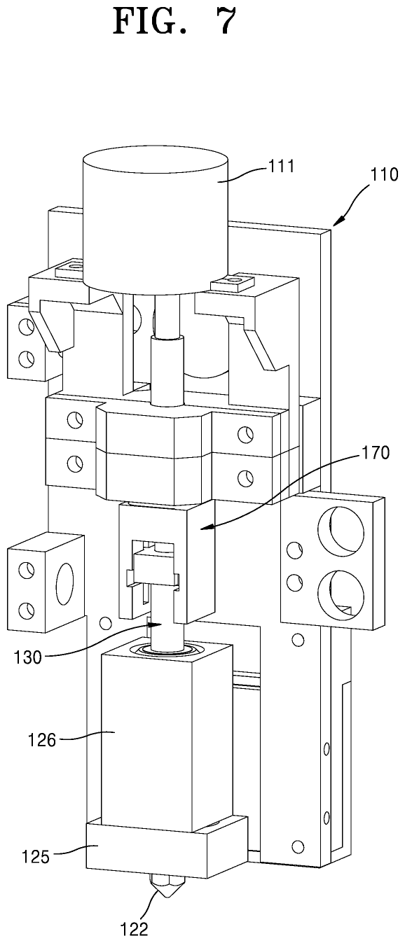

Referring to FIG. 7, the dispenser 120 may include a heating block 125 provided at the lower portion of the dispenser 120 and a heat blocking unit 126 provided at the upper portion of the dispenser 120. Here, a material of the heating block 125 preferably has higher thermal conductivity than a material of the heat blocking unit 126.

To efficiently output a raw material through the dispenser 120, it is preferable to intensively heat the lower portion of the dispenser 120 where the nozzle 122 is arranged. However, a dispenser in the related art has a problem in that a lower portion of the dispenser cannot be intensively heated as the entire dispenser is heated.

To solve the above problem, the dispenser 120 according to an embodiment includes the heat blocking unit 126, which is difficult to be heated due to low thermal conductivity thereof, at the upper portion of the dispenser 120, and the heating block 125, which is easily heated due to high thermal conductivity thereof, at the lower portion of the dispenser 120.

As the heat blocking unit 126 is provided at the upper portion of the dispenser 120, heat of the heating block 125 may be prevented from being transferred to the entire dispenser 120. Accordingly, the raw material may be efficiently output through the dispenser 120.

The heat blocking unit 126 preferably includes a polyether ether ketone (PEEK) material, but is not limited thereto, and may include various materials as long as being able to block heat transferred from the heating block 125 due to its low thermal conductivity.

The heating block 125 may include aluminum or steel having high thermal conductivity, but is not limited thereto, and may include various materials as long as having a higher thermal conductivity than the heat blocking unit 126.

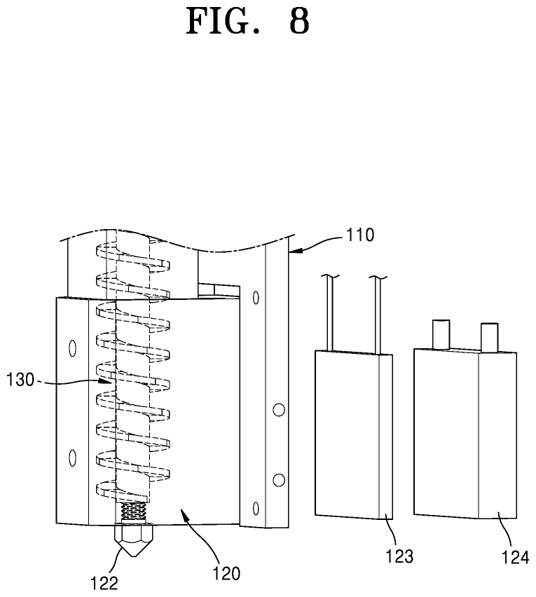

Referring to FIG. 8, the 3D printer using the screw extruder according to an embodiment may further include a Peltier element 123 having one side and another side respectively being cooled or heated according to a direction of a supplied current and coupled to the dispenser 120, and a heater coupled to the dispenser 120 and transferring heat to the dispenser 120.

The one side and the other side of the Peltier element 123 are cooled or heated according to the direction of the supplied current. The Peltier element 123 is an element having one side (or one surface) which may be cooled and another side (or another surface) which may be heated as current flows.

The cooling and heating points of the Peltier element 123 are changed when the direction of the supplied current is changed. In particular, when the direction of the current is changed, the one side (or one surface) of the Peltier element 123 that has been cooled is heated, and the other side of the Peltier element 123 that has been heated is cooled. The Peltier element 123 is used when controlling the dispenser 120 to a low temperature, and the dispenser 120 may be cooled through the Peltier element 123.

A heatsink 124 may be provided on the other side of the Peltier element 123, wherein the other side is heated. As described above, the Peltier element 123 is an element having one side (or one surface) which may be cooled and another side (or another surface) which may be heated as current flows.

To improve a cooling function through the Peltier element 123, there is a need to cool the heat generated from the other side of the Peltier element 123 being heated. The heatsink 124 is used to cool the other side of the Peltier element 123, which is heated, and heat generated from the other side of the Peltier element 123 may be dispersed through the heatsink 124.

The heatsink 124 preferably includes a copper heatsink, but is not limited thereto, and may include various materials as long as being able to disperse heat generated from the other side of the Peltier element 123. For example, the heatsink 124 may include metal.

The heater is coupled to the dispenser 120 and transfers heat to the dispenser 120. The dispenser 120 may be heated through the heater.

The 3D printer using the screw extruder according to an embodiment may further include a sensor unit capable of measuring the temperature of a raw material stored in the dispenser 120 and a controller controlling the Peltier element 123 and the heater according to the temperature of the sensor unit.

The sensor unit may measure the temperature of the raw material stored in the dispenser 120. The sensor unit is coupled to the dispenser 120, and various devices may be used as the sensor unit as long as being able to measure the temperature of the raw material stored in the dispenser 120, and may be coupled to various points of the dispenser 120.

The controller may control the Peltier element 123 and the heater according to the temperature of the sensor unit. In particular, the controller operates the heater to heat the dispenser 120 when the temperature detected by the sensor unit is lower than a designated temperature (target temperature), and operates the Peltier element 123 to cool the dispenser 120 when the temperature detected by the sensor unit is higher than the designated temperature (target temperature).

The 3D printer using the screw extruder according to an embodiment may include a metal-oxide-semiconductor field-effect transistor (MOSFET) connecting the controller and the Peltier element 123 to each other, and a diode may be provided between the Peltier element 123 and the MOSFET. The MOSFET is connected to a voltage supply unit while being provided between the controller and the Peltier element 123, and may receive power.

When one side (or one surface) of the Peltier element 123 and another side (or another surface) thereof are heated and cooled, electricity may be generated in the Peltier element 123 due to a power generating effect. In particular, when a temperature difference occurs between both sides of the Peltier element 123, a reverse voltage is generated due to power generation.

When the dispenser 120 is heated by the heater without using the Peltier element 123, power generation occurs due to the temperature difference between both sides of the Peltier element 123 while the one side (or one surface) of the Peltier element 123 is heated, and accordingly, a reverse voltage enters the MOSFET, and the MOSFET may fail.

That is, when one surface of the Peltier element 123 is heated by the heater, current flows from the Peltier element 123 to the MOSFET, and the MOSFET may be broken. The diode is provided between the Peltier element 123 and the MOSFET to prevent the above case.

The diode allows current to flow in only one direction, and the diode may allow current to flow only in the direction of the Peltier element 123 in the MOSFET. A current may be prevented from flowing in the direction of the MOSFET from the Peltier element 123 through the diode, and accordingly, failure of the MOSFET may be prevented.

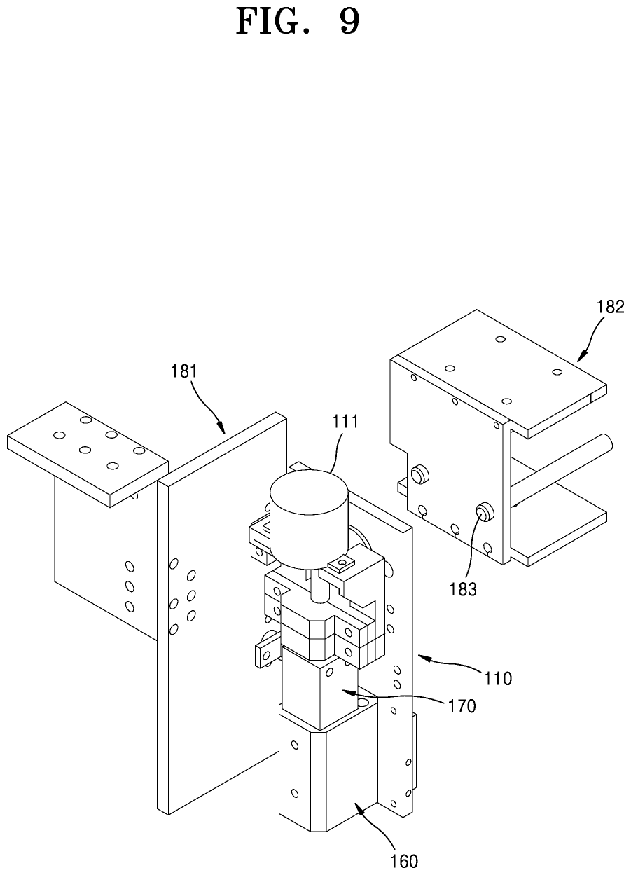

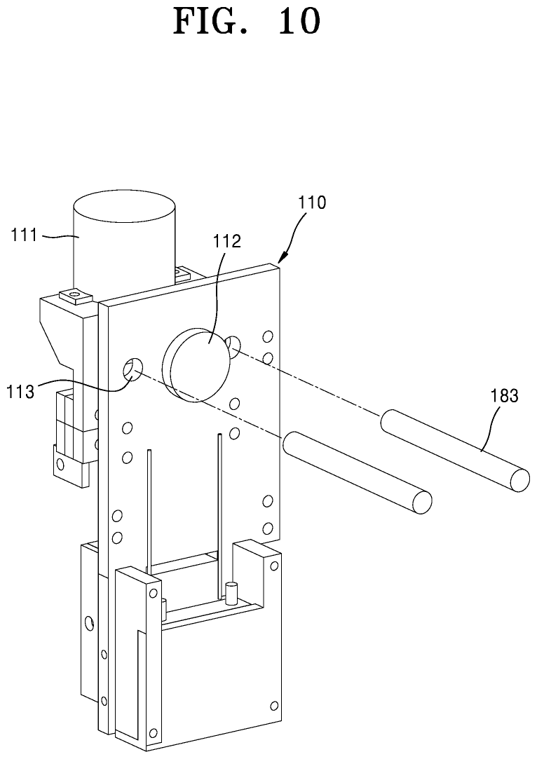

Referring to FIGS. 9 and 10, a magnet 112 for fixing the housing 110 to a support may be provided in the housing 110 of the 3D printer using the screw extruder according to an embodiment.

To proceed with the 3D printer, a plurality of housings 110 each including the dispenser 120 may be provided. A 3D printing operation may be performed by selecting a necessary housing 110 from among the plurality of housings 110. The housing 110 may be coupled to a work support 182 to perform the 3D printing operation, and may be coupled to a fixed support 181 when the 3D printing operation is not performed.

In this way, the magnet 112 may be used to couple the housing 110 to the work support 182 and the fixed support 181 while using the plurality of housings 110.

In the related art, a process for coupling a housing to a support was complicated, but in the 3D printer using the screw extruder according to an embodiment, the housing 110 may be easily coupled to and separated from the work support 182 or the fixed support 181 through the magnet 112.

The magnet 112 provided in the housing 110 may protrude outward of the housing 110, and the work support 182 and the fixed support 181 may each include a groove corresponding to the shape of the magnet 112.

As each of the work support 182 and the fixed support 181 has a groove corresponding to the shape of the magnet 112, the housing 110 may be accurately coupled to a target point.

To couple the housing 110 to the work support 182 or the fixed support 181, a support rod 183 may be used together with the magnet 112. The support rod 183 is coupled to a support to fix the housing 110, and as the support rod 183 is coupled to the housing 110 and the support at the same time, the housing 110 may be firmly coupled to the support.

The support rod 183 may be coupled to the work support 182 or the fixed support 181, a through hole 113 into which the support rod 183 is inserted may be provided in the housing 110.

One side of the support rod 183 may be coupled to the housing 110 while passing the support rod 183 through the through hole 113, and another side of the support rod 183 may be coupled to the work support 182 or the fixed support 181.

The 3D printer using the screw extruder according to the embodiment described above has the following effects.

In the 3D printer using the screw extruder according to an embodiment, cleaning and sterilizing of the 3D printer may be easily performed as a dispenser including a screw forming unit on which a spiral screw is formed is coupled to a housing of the 3D printer in a replaceable manner.

In the 3D printer using the screw extruder according to an embodiment, a dispenser may be detachably coupled to a housing through an accommodating portion and a cover portion of the housing, a key groove is formed in a screw connector connecting a driving motor and an extension portion of the screw extruder, and a coupling key is formed in the extension portion of the screw extruder, and thus the screw extruder may be easily separated from and coupled to the driving motor.

In the 3D printer using the screw extruder according to an embodiment, as a first spring is provided in the screw connector, an output efficiency of the printer may be improved while preventing a backflow phenomenon of a raw material in the dispenser by pressurizing the screw extruder.

In the 3D printer using the screw extruder according to an embodiment, as the inclinations of a first screw and a second screw provided in the screw forming unit are made different from each other, the output efficiency of the printer may be improved, and as a heating block is provided at a lower portion of the dispenser and a heat blocking unit is provided at an upper portion of the dispenser, the output efficiency of the printer may be improved.

The 3D printer using the screw extruder according to an embodiment may control the 3D printer to a low temperature by using a Peltier element and control the 3D printer to a high temperature by using a heater.

In the 3D printer using the screw extruder according to an embodiment, the housing including the dispenser may be easily attached to and detached from a support through a magnet.

As such, the disclosure has been described with reference to one embodiment shown in the drawings, but this is only an example, and those skilled in the art will understand that various modifications and variations of the embodiments are possible therefrom. Accordingly, the true technical scope of protection of the disclosure should be determined by the technical spirit of the appended claims.

1. A 3D printer in which, while raw materials sprayed from the 3D printer are stacked, the raw materials are molded into a sculpture, the 3D printer comprising:
a housing comprising a driving motor;
a dispenser in which raw materials are stored, comprising a nozzle through which raw materials are sprayed;
a screw extruder comprising a screw forming unit arranged inside the dispenser, having a rod shape, and comprising a spiral screw formed on an outer circumferential surface, and an extension portion extending from the screw forming unit to outside of the dispenser; and
an accommodating portion provided in the housing and to which the dispenser is coupled,
wherein the dispenser is detachably coupled to the accommodating portion of the housing.

2. The 3D printer of claim 1, wherein the accommodating portion has one surface open toward outside, and
the 3D printer further comprises a cover portion coupled to the one surface of the accommodating portion.

3. The 3D printer of claim 1, wherein the dispenser comprises a material replenishing port configured to inject raw materials into the dispenser.

4. The 3D printer of claim 1, further comprising a screw connector connecting the driving motor and the extension portion of the screw extruder to each other.

5. The 3D printer of claim 4, wherein a key groove into which the extension portion is able to be inserted is formed at a lower portion of the screw connector, and
an upper portion of the extension portion is provided with a coupling key having a shape corresponding to a shape of the key groove to be able to be inserted into the key groove.

6. The 3D printer of claim 5, wherein a first spring capable of applying an elastic restoring force to the extension portion is provided at an upper portion of the key groove.

7. The 3D printer of claim 5, wherein a first spring capable of applying an elastic restoring force to the extension portion is provided at an upper portion of the key groove, and
a spring plate in contact with the coupling key of the extension portion is provided between the first spring and the key groove.

8. The 3D printer of claim 1, wherein the screw forming unit comprises a first screw forming unit arranged at a lower portion of the dispenser and a second screw forming unit arranged at an upper portion of the dispenser, and
an inclination formed by a second screw of the second screw forming unit is higher than an inclination formed by a first screw of the first screw forming unit.

9. The 3D printer of claim 5, wherein a sealing unit capable of sealing an upper portion of the screw forming unit is provided at a lower portion of the extension portion.

10. The 3D printer of claim 9, wherein the sealing unit is slidably coupled between the screw forming unit and the coupling key of the extension portion, and
a second spring is inserted between the coupling key of the extension portion and the sealing unit.

11. The 3D printer of claim 1, further comprising:
a Peltier element having one side and another side being cooled or heated according to a direction of a supplied current, and coupled to the dispenser; and
a heater coupled to the dispenser and configured to transfer heat to the dispenser.

12. The 3D printer of claim 11, further comprising a sensor unit capable of measuring a temperature of raw materials stored in the dispenser, and a controller configured to control the Peltier element and the heater according to a temperature sensed by the sensor unit,
wherein the controller operates the heater when the temperature sensed by the sensor unit is lower than a designated temperature, and operates the Peltier element when the temperature sensed by the sensor unit is higher than the designated temperature.

13. The 3D printer of claim 1, wherein the dispenser comprises: a heating block provided at a lower portion of the dispenser; and a heat blocking unit provided at an upper portion of the dispenser, and
a material of the heating block has a higher thermal conductivity than a material of the heat blocking unit.

14. The 3D printer of claim 1, wherein the housing comprises a magnet configured to fix the housing to a support.

15. The 3D printer of claim 1, wherein the housing comprises a through hole into which a support rod is inserted, and the support rod is coupled to a support configured to fix the housing.
